(19) United States
(12) Patent Application Publication
(10) Pub. No.: US 2025/0239540 A1
(43) Pub. Date: Jul. 24, 2025

(54) SYSTEMS AND METHODS FOR PROVIDING NON-CONTACT PROTECTION FEATURES IN SEMICONDUCTOR DEVICES

(71) Applicant: The Charles Stark Draper Laboratory, Inc., Cambridge, MA (US)

(72) Inventors: William Roy, Cambridge, MA (US); Richard H. Morrison, Taunton, MA (US)

(21) Appl. No.: 19/026,960

(22) Filed: Jan. 17, 2025

Related U.S. Application Data
(60) Provisional application No. 63/623,892, filed on Jan. 23, 2024.

(51) Int. Cl. H01L 23/00; H01L 21/268; H01L 21/67

(52) U.S. Cl. CPC H01L 23/573; H01L 21/268; H01L 21/67092

(57) ABSTRACT

A system includes an input for receiving a data representation of a semiconductor device. The semiconductor device has a device body with a first side and an opposing second side, the first side being separated from the second side by a thickness of the device body, a first side separated from an opposing second side by the thickness, and one or more semiconductor dies. The system also includes a laser configured to emit a collimating beam and one or more processors, coupled with memory. The processors are configured to process the data representation of the semiconductor device to construct a pattern of protection features based on locations of the one or more semiconductor dies on the semiconductor device and actuate the laser to emit the collimating beam to create protection features in the semiconductor device according to the pattern, while maintaining the thickness of the device body within a threshold range.

### CROSS-REFERENCES TO RELATED APPLICATIONS

This application claims the benefit of U.S. Provisional Application No. 63/623,892 filed Jan. 23, 2024, the entire contents of which are incorporated herein by reference. This present application also incorporates by reference U.S. Provisional Application No. 63/590,815, entitled “Semiconductor Having a Functional Protection Structure and Method of Manufacture” and filed Oct. 17, 2023.

### TECHNICAL FIELD

Aspects of the disclosure generally relate to systems and methods for production of a semiconductor device. In particular, the systems and methods disclosed herein relate to actuating a laser to provide protection features.

### BACKGROUND

A semiconductor device can include a substrate with one or more dies disposed within the substrate. In some cases, one or more of the dies can include a circuit to perform an electrical function.

### SUMMARY

Presented herein are systems and methods for providing protection features in semiconductor devices. A system can include a semiconductor device. The semiconductor device can include one or more semiconductor dies disposed within a substrate of the semiconductor device. Each semiconductor die can be configured to provide a functionality prescribed by one or more circuits included within the semiconductor die. In some cases, a protection feature can be disposed within the semiconductor device to cause one or more dies to fracture upon an application of a threshold stress.

Fabricating these protection features can include fabrication difficulties such as inconsistencies within the semiconductor device and limitations on placement of the protection features. Present manufacturing for protection features can cause the protection features to lack consistency in sizing or spacing across the semiconductor device. These inconsistencies in protection features can reduce precision of the protection feature's tuning, potentially causing the dies to fracture at a force outside of a selected force range. Scalability of semiconductor devices with protection features can suffer as a result of protection feature inconsistencies, as each protection feature may necessitate validation individual testing to ensure conformance to a tolerance.

Furthermore, creating protection features within the semiconductor device can cause the semiconductor device itself to crack, snap, or fracture, thereby potentially destroying multiple dies at once. Contact-type manufacturing of protection features, such as drilling or etching, can cause vibrations across the semiconductor device. These vibrations can cause fracturing of the semiconductor device. Moreover, the fracturing of the semiconductor device can be exacerbated by limitations imposed by a thickness of the semiconductor device during manufacturing. For example, in some conventional systems a semiconductor device can be thinned to provide the protection features in the semiconductor device within a threshold distance of a die. By thinning the semiconductor device to dispose the protection features, the semiconductor device can become more prone to breakage than an un-thinned semiconductor device. Additionally, thinning the semiconductor device can, in some cases, necessitate additional processing to mitigate the fragilities of the thinned semiconductor device, such as adding a cap or handle to the thinned semiconductor device.

To account for these and other technical problems, protection features may be provided with non-contact etching. Non-contact etching can include a laser providing a beam. The laser can generate a collimated beam of light which, upon passing into the substrate, can converge within the substrate. At a point of convergence of the beam within the substrate, the beam can cause a portion of the substrate can change in structure to become a protection feature. The laser can provide the beam to trepan the semiconductor device according to a pattern. In this manner, multiple protection features can be provided by the beam of the laser at multiple locations with the semiconductor device, such as any depth or planar (e.g., lateral) position, without causing undue vibrations.

By implementing non-contacting etching via a beam of a laser, the systems and methods described herein can provide for consistent, precise, and scalable protection features within a semiconductor device. Furthermore, by enabling fabrication of these protection features with a thicker semiconductor device, reduction of vibrations encountered by the semiconductor device and deficiencies within the semiconductor devices can be decreased. In this manner, efficiency of the production of the protection features can be increased, by reducing defects and breakage in the semiconductor device as compared to traditional systems. As such, the systems and methods described herein provide an improvement to the production of protection features for semiconductor devices.

In a general aspect, a system includes an input for receiving a data representation of a semiconductor device. The semiconductor device has a device body with a first side and an opposing second side, the first side being separated from the second side by a thickness of the device body, a first side separated from an opposing second side by the thickness, and one or more semiconductor dies. The system also includes a laser configured to emit a collimating beam and one or more processors, coupled with memory. The processors are configured to process the data representation of the semiconductor device to construct a pattern of protection features based on locations of the one or more semiconductor dies on the semiconductor device and actuate the laser to emit the collimating beam to create protection features in the semiconductor device according to the pattern, while maintaining the thickness of the device body within a threshold range.

Aspects may have one or more of the following features.

The laser may emit the collimating beam to the second side of the semiconductor device to provide the protection features according to the pattern. The protection features may be configured to reduce a tensile strength of at least one of the semiconductor dies. The one or more processors may be further configured to cause a light source to illuminate the semiconductor device, cause an imaging device to image the illuminated semiconductor device, and validate the protection features created in the semiconductor device, including processing the image of the illuminated semiconductor device according to the pattern of protection features.

The pattern of protection features may include parameter values for configuring the laser. The pattern of protection features may map at least one of the semiconductor dies to one or more of the protection features. The collimating beam may converge at a point disposed within the device body of the semiconductor device, based on the pattern of protection features, to create at least one of the protection features. Creating at least some of the protection features may include using the collimated light to change a portion of the device body of the semiconductor device from a crystalline state to an amorphous state.

Each protection feature may correspond to a respective die of the dies. The threshold range may be between 50 μm to 800 μm. The threshold range may be between 250 μm to 800 μm. A first protection feature of the protection features may differ from a second protection feature of the protection features in at least a depth within the semiconductor device, size, or structure. The one or more semiconductor dies may include at least one semiconductor feature disposed within the first side of the semiconductor device. The pattern may define a set of three-dimensional coordinates for creating the protection features.

In another general aspect, a method includes receiving a data representation of a semiconductor device having a device body with a first side and an opposing second side, the first side being separated from the second side by a thickness of the device body, a first side separated from an opposing second side by the thickness, and one or more semiconductor dies. The method also includes processing the data representation of the semiconductor device to construct a pattern of protection features based on locations of the one or more semiconductor dies on the semiconductor device, and actuating a laser to emit a collimating beam to create protection features in the semiconductor device according to the pattern, while maintaining the thickness of the device body within a threshold range.

Aspects may include one or more of the following features.

The laser may emit the collimating beam to the second side of the semiconductor device to provide the protection features according to the pattern. The threshold range may be between 50 μm to 800 μm. The method may include causing a light source to illuminate the semiconductor device, causing an imaging device to image the illuminated semiconductor device, and validating the protection features created in the semiconductor device, including processing the image of the illuminated semiconductor device according to the pattern of protection features. The collimating beam may converge at a point disposed within the semiconductor device, based on the pattern of protection features, to create at least one of the protection features.

In another general aspect, a semiconductor device includes a device body with a first side and an opposing second side, the first side being separated from the second side by the thickness of the device body, a first side separated from an opposing second side by the thickness, one or more semiconductor dies, and one or more protection features disposed in the device body and configured to reduce a tensile strength of at least one of the semiconductor dies, wherein at least some of the one or more protection features include material in an amorphous state.

At least one aspect of the present disclosure is directed to a system for providing protection features in semiconductor devices. The system can include a semiconductor device. The semiconductor device can have a thickness. The semiconductor device can include a first side separated from an opposing second side by the thickness. The semiconductor device can include one or more semiconductor dies. The system can include a laser configured to provide a collimating beam. The system can include one or more processors, coupled with memory. The one or more processors can construct a pattern of protection features based on the semiconductor dies. The one or more processors can actuate the laser to provide the collimating beam to create protection features in the semiconductor device according to the pattern, while maintaining the thickness within a threshold range.

In some aspects, the laser can provide the collimating beam to the second side of the semiconductor device to provide the protection features according to the pattern. In some aspects, the protection features can reduce a tensile strength of at least one of the semiconductor dies. In some aspects, the one or more processors can project, via a light source, a ray of light towards the semiconductor device. In some aspects, the one or more processors can validate, responsive to actuating the laser, the provided protection features based on the ray of light and the pattern of protection features.

In some aspects, the pattern of protection features can include settings indicating control of the laser. In some aspects, the pattern of protection features can map at least one of the semiconductor dies to one or more of the protection features. In some aspects, the collimating beam can converge at a point disposed within the semiconductor device, based on the pattern of protection features, to create at least one of the protection features. In some aspects, to provide the protection features in the semiconductor device according to the pattern of protection features, the collimating beam can change a portion of the semiconductor device from a crystalline state to an amorphous state.

In some aspects, each protection feature can correspond to a respective die of the dies. In some aspects, the threshold range can be between 250 μm to 800 μm. In some aspects, a first protection feature of the protection features can differ from a second protection feature of the protection features in at least a depth within the semiconductor device, size, or structure. In some aspects, each of the protection features provided in the semiconductor device can be separated by at least 80 μm. In some aspects, the one or more semiconductor dies can include at least one semiconductor feature disposed within the first side of the semiconductor device. In some aspects, the pattern can define a set of three-dimensional coordinates for creating the protection features.

At least one aspect of the present disclosure is directed to a method. The method can include receiving, by one or more processors coupled with memory, a semiconductor device having a thickness. The semiconductor device can include a first side separated from an opposing second side by the thickness. The semiconductor device can include one or more semiconductor dies. The method can include constructing, by the one or more processors, a pattern of protection features based on the semiconductor dies. The method can include actuating, by the one or more processors, a laser to provide a collimating beam to provide protection features in the semiconductor device according to the pattern, while maintaining the thickness within a threshold range.

In some aspects, the method can include actuating, by the one or more processors, the laser to provide the collimating beam to the second side of the semiconductor device to provide the protection features according to the pattern. In some aspects, the protection features can reduce a tensile strength of at least one of the semiconductor dies. In some aspects, the threshold range can be between 250 μm to 800 μm. In some aspects, the method can include projecting, by the one or more processors via a light source, a ray of light towards the semiconductor device. The method can include validating, by the one or more processors responsive to actuating the laser, the provided protection features based on the ray of light and the pattern of protection features. In some aspects, the collimating beam can converge at a point disposed within the semiconductor device, based on the pattern of protection features, to create at least one of the protection features.

At least one aspect of the present disclosure is directed to a semiconductor device. In some aspects, the semiconductor device can include a thickness between a first side separated from an opposing second side. The semiconductor device can include one or more semiconductor dies. The semiconductor device can include protection features disposed by a laser at the second side according to a pattern of protection features.

Some aspects advantageously create a protection feature that is enclosed by a die boundary and is confined to a portion of the circuit such that the protection features result in tamper-proof dies that do not break when multiple dies are separated from one another in normal processing. For example, in some aspects, a laser collimating process is used to form a narrow buried distressed region inside a wafer at a certain precise depth. The depth is highly repeatable due to the consistent nature of the silicon wafer's crystal lattice. The distressed region is formed at a given depth by moving either the laser or the wafer according to a pattern in the x,y axes of the wafer and at different depths (i.e., the z axis of the wafer). Some aspects tune the x,y,z parameters as well as intensity level and beam movement rate of the laser to achieve silicon crystal which is broadly stable except under specific conditions. Under these conditions, and by leveraging the repeatable fracture behavior of highly predictable silicon crystal lattice, cracks in the silicon device that are detrimental to its function can be induced. So, instead of a sequence of uninterrupted “stacked” distressed regions forming a crack easily, aspects may form interruptions in the laser energy delivery to skip layers (in z axis), or to create an dotted line (vs a solid line) of disturbed silicon in the x or y axis. Depending on the overall patterning placement, certain regions (e.g., regions in close proximity to electrical features of a die can be made predictably and irreversibly reactive to abnormal stresses (i.e., outside of stresses typically experienced during the fabrication and assembly processing of the device).

### BRIEF DESCRIPTION OF THE DRAWINGS

The foregoing and other objects, aspects, features, and advantages of the disclosure will become more apparent and better understood by referring to the following description taken in conjunction with the accompanying drawings. The accompanying drawings are not intended to be drawn to scale. Like reference numbers and designations in the various drawings indicate like elements. For purposes of clarity, not every component may be labeled in every drawing. In the drawings:

FIG. 1 illustrates a block diagram of a system for providing protection features in semiconductor devices;

FIG. 2 illustrates a view of a semiconductor device being fabricated to include protection features;

FIGS. 3A-3B illustrate a process to fabricate a semiconductor device with protection features; and

FIG. 4 illustrates a top view of a semiconductor device with protection features.

### DETAILED DESCRIPTION

Reference will now be made to the embodiments illustrated in the drawings, and specific language will be used here to describe the same. It will nevertheless be understood that no limitation of the scope of the disclosure is thereby intended. Alterations and further modifications of the features illustrated here, and additional applications of the principles as illustrated here, which would occur to a person skilled in the relevant art and having possession of this disclosure, are to be considered within the scope of the disclosure.

Described herein are systems and methods for providing protection features in semiconductor devices. Fabricating these protection features can cause inconsistencies within the semiconductor device and fabrication difficulties. Present manufacturing for protection features can cause the protection features to lack consistency in sizing or spacing across the semiconductor device. These inconsistencies in protection features can reduce precision of the protection feature's tuning to break at a selected force. Additionally, contact-based fabrication of protection features within the semiconductor device can cause the semiconductor device itself to crack, snap, or fracture. Furthermore, validation of protection features can be time-consuming and prone to error.

To account for these and other technical problems, a laser can generate a collimated beam of light, which, upon passing into a substrate of the semiconductor device, can converge within the substrate to generate protection features, resulting in a tamper-proof semiconductor device. At a point of convergence of the beam within the substrate, the substrate can change in structure to become a protection feature. By implementing non-contacting etching via the beam of a laser, the systems and methods described herein can provide for consistent, precise, and scalable protection features within a semiconductor device.

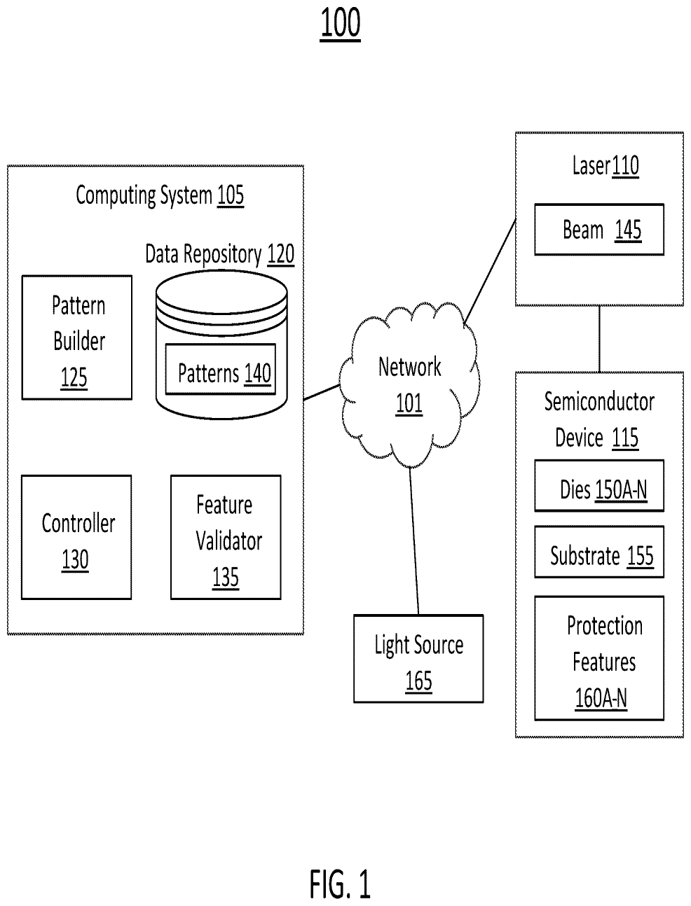

FIG. 1 depicts a block diagram of a system 100 for providing protection features in semiconductor devices. The system 100 can include a computing system 105 communicatively coupled via a network 101, a laser 110, a semiconductor device 115, or a light source 165, among others. The computing system 105 can include a pattern builder 125, a data repository 120 including patterns 140, a controller 130, or a feature validator 135, among others. The semiconductor device 115 can include one or more dies 150A-N, a substrate 155, or one or more protection features 160A-N.

In brief overview of the system 100, the pattern builder 125 can construct a pattern 140 based on one or more of the subcomponents (e.g., the dies 150A-N, the substrate 155, or the protection features 160A-N) of the semiconductor device 115; the controller 130 can transmit instructions to the laser 110 to provide a beam 145 to generate the protection features 160 in the semiconductor device 115 according to the identified pattern 140. The feature validator 135 can generate instructions to actuate the light source 165 to verify the protection features 160 in the semiconductor device 115. Embodiments can comprise additional or alternative components or omit certain components from those of FIG. 1, and still fall within the scope of this disclosure.

The network 101 can include various hardware and software components of one or more public or private networks, which can interconnect the various components of the system 100. Non-limiting examples of such networks can include Local Area Network (LAN), Wireless Local Area Network (WLAN), Metropolitan Area Network (MAN), Wide Area Network (WAN), and the Internet. The communication over the network can be performed in accordance with various communication protocols, such as Transmission Control Protocol and Internet Protocol (TCP/IP), User Datagram Protocol (UDP), and IEEE communication protocols, among others. In some cases, the network 101 can include a hardwired connection, such as fiber optic, copper, ethernet or other electrically or communicatively conductive wiring or other communications cables to transmit communication, power, or other signals among the various components of the system 100, such as the laser 110.

The laser 110 can be or include any device to produce light at a specified wavelength, direction, or polarization. The laser 110 can emit a beam 145 of light that exhibits one or more characteristics. The characteristics can include a polarization of the light, an intensity of the light, a wavelength or frequency of the light, an amplitude of the light, a direction of the light, or a magnification of the light, among others. In some cases, the laser can provide the beam 145 as a collimated beam 145. The collimated beam 145 can be or include a parallel ray or rays of light emitted by the laser 110. In some cases, the laser 110 can project the beam 145 towards, at, in direction of the semiconductor device 115. The laser 110 can produce, provide, or emit the collimated beam 145 at such an intensity, focus, or power as to change one or more portions of the semiconductor device 115 into protection features 160A-N, as described herein.

The semiconductor device 115 can be a single or multilayered structure to provide an electric functionality. In some cases, the semiconductor device 115 can be or include a microelectronic device. The semiconductor device 115 can include the dies 150A-N (hereinafter generally referred to as the die(s) 150), the substrate 155, or the protection features 160A-N (hereinafter generally referred to as the protection feature(s) 160), among others. It should be noted that the semiconductor device 115 can include other or additional subcomponents, such as an insulating material, handle, or cap, among others. In some cases, the semiconductor device 115 can include a first side and a second side. In some cases, the first and second side can oppose each other. For example, the first and second side can be parallel to each other and can be separated by a thickness orthogonal to at least one of the first or second sides. For example, the first and second side can be orthogonal to each other and can be separated by a thickness. In some cases, the first and second side can be offset from each other. The first and second side can be the same shape or a different shape. For example, the first side and the second side can include a disk, wafer, or other such shape with a thickness of the semiconductor device (composed, for example, of the substrate 155) coupling the two sides together.

In some cases, the semiconductor device 115 can provide structures such as transistors, diodes, or other semiconductor structures with one or more of the dies 150. The dies 150 can include one or more electronic circuits including electronic structures. The electronic structures can include semiconductor structures (e.g., bipolar junction transistors (BJTs), light-emitting diodes (LEDs), field effect transistors (FETs), thyristors, etc.) or non-semiconductor structures (e.g., resistors, capacitors, inductors, etc.), among others. The electronic structures of the die 150 can be connected through traces, vias, or other such conductors. In this manner, each die can include one or more integrated circuits including one or more electronic structures arranged to provide an electric functionality.

The dies 150 can be disposed with the substrate 155 of the semiconductor device 115. In some cases, the dies 150 can be disposed in the first side of the semiconductor device, such as disposed with the substrate 155 of the semiconductor device. The dies 150 can intrude or extrude from one or more of the sides of the semiconductor device 115. For example, the dies 150 can be coupled with, inserted into, or extruding from the first side of the semiconductor device 115. In some aspects, each die 150 disposed within the substrate 155 can include the same integrated circuit. In some cases, the dies can be disposed at intervals within the substrate, as to form an array or pattern of the dies 150 within the substrate 155.

The substrate 155 can include or be composed of a semiconductor material such as silicon, germanium, or gallium arsenide, among others. In some cases, the semiconductor material of the substrate 155 can include a crystalline structure, such as a cubic symmetrical structure, tetrahedron structure, octahedron structure, etc. The crystalline structure of a semiconductor material can conform to or be defined by a crystallographic plane, such as (100), (110), or (111) plane, in accordance with Miller indices. In this manner, certain semiconductor materials of which the substrate 155 can be composed can be referred to as, for example, (100) silicon, (100) germanium, 110 silicon, 111 silicon, etc., according to the Miller index associated with the crystal orientation of the substrate 155.

Structural properties of the semiconductor device 115 can exhibit or relate to optical properties of the substrate 155. The substrate 155 can exhibit different opacities or transparencies for different wavelengths and crystalline structures based on a composition of the substrate 155. In some cases, one or more wavelengths of light can exhibit different transparencies when shone upon the substrate 155. For example, crystalline silicon can be opaque (e.g., not allow light to pass) at wavelengths within the visible light spectrum (e.g., 400-800 nm). In a similar manner, crystalline silicon can be transparent to (e.g., allow light to pass) wavelengths in the infrared (IR) region, such as wavelengths above 1.1 μm, for example. As another example, crystalline gallium arsenide can be opaque at wavelengths within the visible light spectrum, but transparent to wavelengths at 850 nm and above. As another example, zinc-sulfide can be transparent at wavelengths of the visible light range, but opaque at wavelengths approaching the ultraviolet region (e.g., 400 nm and below).

The substrate 155 can include different structural compositions, crystalline structures, amorphous structures, or fluid structures, among others. In some cases, the structural composition of the substrate 155 can impact a transparency of the substrate 155. For example, zinc-sulfide in its cubic crystalline form (also known as sphalerite) does not possess the same transparency at visible light spectrums as zinc-sulfide in its hexagonal form (also known as the wurtzite crystal structure). As another example, although crystalline silicon is transparent to IR light, amorphous silicon is less transparent or opaque to IR light. Amorphous silicon can be silicon which does not exhibit a crystalline structure, but rather an undefined structure characterized by random alignment of silicon atoms. Amorphous silicon can be opaque to IR light, such as IR cast by the light source 165.

The light source 165 can be any lamp, light, or illumination to emit light. For example, the light source can be or include an incandescent light, a light-emitting diode (LED), a compact fluorescent lens (CFL), among others. In some cases, the light source 165 can provide one or more wavelengths of light. For example, the light source 165 can provide light in the IR range, the UV range, the visible light spectrum, among others. The light source 165 can provide light at any periodicity, such as continuously, pulse-width modulation (PWM), or sinusoidal.

The computing system 105 can include a pattern builder 125. The pattern builder 125 can be any combination of hardware and software designed, constructed, or operational to construct the pattern 140 of protection features. The pattern builder 125 can construct the pattern 140 based on the semiconductor device 115, such as based on the dies 150 of the semiconductor device 115.

The pattern 140 can be a pattern of the protection features 160. The protection features 160 can be areas, points, or inclusions to reduce a tensile strength of at least one of the dies 150. The protection features 160 can be made of a material of the semiconductor device 115, such as the substrate 155. For example, the protection features 160 can be formed from crystalline silicon of the substrate 155. In some cases, the protection features 160 can be inserted into the semiconductor device 115. For example, the protection features 160 can be located between the first side and the second side of the semiconductor device. The protection features 160 can be a break, malformity, inclusion, indent, or other such disruption of the substrate 155 material.

A location for each protection feature of the protection features 160 can be constructed, determined, or identified by the pattern builder 125. The pattern builder 125 can determine a location within the semiconductor device 115 to place the one or more protection features 160. The pattern builder 125 can construct the pattern to select a position of the protection features. For example, the pattern builder can construct the pattern to select a position for each protection feature based on a 2-dimensional or 3-dimensional coordinate system. The pattern builder 125 can determine a depth position, a lateral position, or other such position or location within the semiconductor device 115 at which to place the protection features 160. The pattern builder 125 can determine a size of the protection features 160. For example, the pattern builder 125 can determine a first protection feature 160A to be larger than a second protection feature 160B.

In some cases, the pattern builder 125 can construct the pattern based on the dies 150. For example, the pattern builder 125 can determine to construct the pattern such that each protection feature 160 maps to a die of the dies 150. Mapping to a die of the dies 150 can refer to a many-to-one or one-to-one association of the protection features 160 to a die 150. Mapping to a die of the dies 150 can include indicating a location for placement of the protection feature 160. For example, a protection feature 160A mapped to a die 150A can be placed within a threshold distance (e.g., depth or lateral position of the semiconductor device 115) of the die 150A, within a threshold size of the protection feature 160, among others. In some cases, one or more dies 150 may not be mapped to by any protection features 160.

The pattern builder 125 can identify the dies 150 to construct the pattern 140. For example, the pattern builder 125 can determine, through an image capture device, electrical feedback, or user input, among others, characteristics of the dies 150 of the semiconductor device 115. Characteristics of the dies 150 of the semiconductor device 115 can include a location of one or more dies 150 within the semiconductor device 115, a size of one or more dies 150 within the semiconductor device 115, an orientation of one or more dies 150 within the semiconductor device 115, a material of one or more dies 150, among others. In some cases, the pattern builder 125 can receive user input to determine the characteristics of the dies 150. For example, the pattern builder 125 can receive input indicating a type of the dies 150, a location of the dies 150, a size of the dies 150, among others.

Based on the characteristics of the dies 150, the pattern builder 125 can construct the pattern 140 of protection features 160. The pattern builder 125 can construct the pattern 140 including mapping of the protection features 160 to one or more dies. The pattern builder 125 can construct the pattern including settings for the laser 110 to provide the protection features 160 in the semiconductor device 115.

The settings can be or include a set of parameters for operation of the laser 110. For example, the settings generated by the pattern builder 125 can include a heat of the beam 145 of the laser 110, a size of a focal point of the beam 145, an intensity of the beam 145, a movement of the laser 110 or the beam 145, a power draw of the laser 110, an angle of the laser 110 or its beam 145, among others, to produce the protection features 150 according to the pattern 140. The pattern builder 125 can provide the pattern 140 to the controller 130.

The computing system 105 can include a controller 130. The controller 130 can be any combination of hardware and software designed, constructed, or operational to actuate the laser 110 according to the pattern 140. The controller 130 can actuate the laser 110 to provide the beam 145 according to the pattern 140 to provide the protection features 160 in the semiconductor device 115. The controller 130 can actuate the laser 110 to provide the protection features 160 to reduce a tensile strength of at least a part of the semiconductor device 115.

The controller 130 can actuate the laser 110 according to the pattern 140. In some cases, the pattern 140 can indicate parameters for the operation of the laser 110, such as an intensity of the laser 110, a focal point of the laser 110, among others. For example, the settings of the pattern 140 can indicate a power of the laser 110, a focal point of the laser 110, an intensity of the laser 110, among others. The controller 130 can cause the laser to move according to the pattern 140. In some cases, the controller 130 can cause the laser 110 to provide the beam 145 to the semiconductor device 115. For example, the pattern 140 can indicate a number of protection features 160, a layout (e.g., lateral position or depth within the semiconductor device 115) of one or more protection features 160, a distance or separation between one or more protection features 160, or a size or shape of a protection features 160, among others. For example, the pattern 140 can indicate an intensity, duration, power, or other parameters for the laser 110 to provide the beam 145 to place, generate, or create the protection features 160 within the semiconductor device 115 according to the constructed pattern 140.

In some cases, the laser 110 can provide the protection features 160 through the beam 145. The beam 145 can cause a material of the semiconductor device 115 to change structurally. For example, the beam 145 can create heat at such a temperature and location to melt a portion of the material of the semiconductor device 115. In this manner, the beam 145 can create inclusions within the material of the semiconductor device 115. In some cases, one or more of these inclusions can be protection features 160. In some cases, the beam 145 can be a collimating beam 145 which converges at a point within the semiconductor device 115. For example, upon the collimating beam 145 entering the semiconductor device 115, the beam 145 can converge at a convergence or focal point. The beam 145 can converge at any depth of the semiconductor device, where the depth of the semiconductor device is a distance at or between the first and second surface of the semiconductor device, measured perpendicularly to the first and second surface of the semiconductor device. At the convergence point of the collimating beam 145, the beam 145 can cause a crystalline structure of the semiconductor device 115 to change from a crystalline state to an amorphous state. For example, the beam 145 can cause a portion of crystalline silicon of the semiconductor device 115 to change to amorphous silicon. In some cases, this portion of amorphous silicon can be or include the protection feature 160. The protection features 160 can be validated by the feature validator 135.

The computing system 105 can include a feature validator 135. The feature validator 135 can be any combination of hardware and software designed, constructed, or operational to actuate the light source 165 to validate the protection features 160 in accordance with the pattern 140. In some cases, the feature validator 135 can project, via the light source 165, a ray of light towards the semiconductor device 115. The feature validator 135 can validate the provided protection features 160 based on the ray of light and the pattern 140 of protection features.

In some cases, the protection features 160 can be opaque to one or more wavelengths of light. The light source 165 can provide at least one wavelength of light at which the protection features 160 are opaque. In some cases, a location, size, or other characteristics of the protection features can be validated against the pattern 140 to reduce defects among the protection features 160 in the semiconductor device 115.

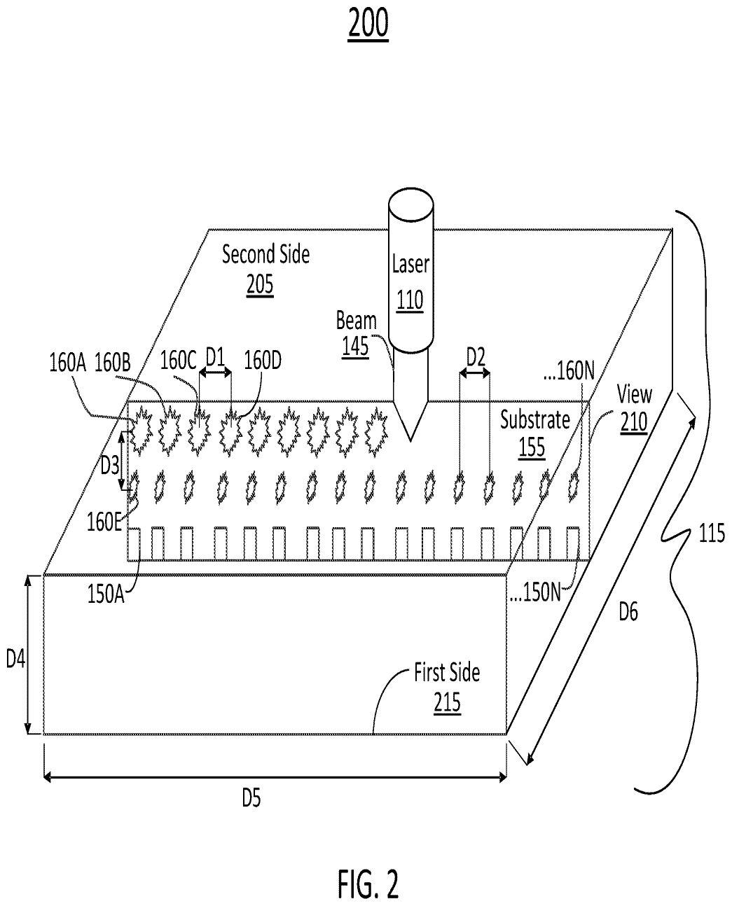

FIG. 2 illustrates a view of a semiconductor device being fabricated to include protection features. The view 200 can include the laser 110, the beam 145, distances D1-D6, the semiconductor device 115, and a view 210. The semiconductor device 115 can include the dies 150, the protection features 160, the distances D1-D6, a first side 215, a second side 205, or the substrate 155. In brief overview, the laser 110 can provide the beam 145 in accordance with the pattern 140 (not pictured) to create the protection features 160. Embodiments can comprise additional or alternative components or omit certain components from those of FIG. 2 and still fall within the scope of this disclosure.

As described with reference to FIG. 1, the laser 110 can provide the beam 145 to create the protection features 160 in the substrate 155. In some cases, the laser can provide the beam to the second side 205. The second side 205 can be opposite a first side 215. In some cases, the dies 150 can be disposed, arranged, or coupled with the first side 215 of the semiconductor device 115. The first side 215 can oppose the second side 205. The first side 215 and the second side 205 can be any shape, such as rounded, angled, rectangular (pictured), elliptical, among others. In some cases, the first side and the second side can be different shapes. The first side 215 and the second side 205 can have a length D5 and a width D6. The length D5 and the width D6 can be between 20 mm to 500 mm.

In some cases, the first side 215 can be separated from the opposing second side 205 by a thickness. The thickness can be the distance D4. In some cases, the distance D4 can be between 250 μm to 800 μm. In some cases, the distance D4 can be between 50 μm to 800 μm. In some cases, the distance D4 can be at least 650 μm. The laser 110 can provide the protection features in the semiconductor device 115 of thickness D4. In some cases, the laser can provide the beam 145 to create the protection features 160 in the semiconductor device 115 while maintaining the thickness D4 within a threshold range. The threshold range can be a tolerance for the thickness D4 and can be between 0-100 μm.

The laser 110 can provide differing protection features 160 within the semiconductor device 115. The view 210 exhibits a cross-sectional view of the semiconductor device 115 extending the thickness D4 (e.g., from the second surface 205 to the first surface 215). The laser 110 can provide a first protection feature 160A on the second surface 205 and a second protection feature 160B within the substrate 155. In some cases, the first protection feature 160A can differ from the second protection feature 160B in at least a depth within the semiconductor device 115, size, or structure. For example, a third protection feature 160C can have a different size, shape, or material structure than a fifth protection feature 160E. In some cases, the protection features 160 can be separated from each other by varying or the same distances. For example, a fourth protection feature 160D can be a distance D1 from the third protection feature 160C. In some cases, the distance D1 can be a distance parallel to an axis of the length D5. As another example, the first protection feature 160A can be separated from a protection feature 160 by a distance parallel to an axis of the width D6. As another example, the first protection feature 160A can be separated from the fifth protection feature 160E by a distance D3. In some cases, the distance D3 can be a distance parallel to an axis of the thickness D4.

The laser 110 can create the protection features 160 separated by the distances D1 and D3, among others. In some cases, the distances D1, D3, or other distances between each protection feature 160 provided by the laser 110 can be at least 80 μm. In some cases, the protection features can be created at any depth within the thickness D4. For example, one or more protection features 160 can be created at a lateral location of the semiconductor device 115 and separated by differing depths. In this manner, depth of the protection features 160 within the semiconductor device 115 can be controlled to a greater degree than that of conventional systems.

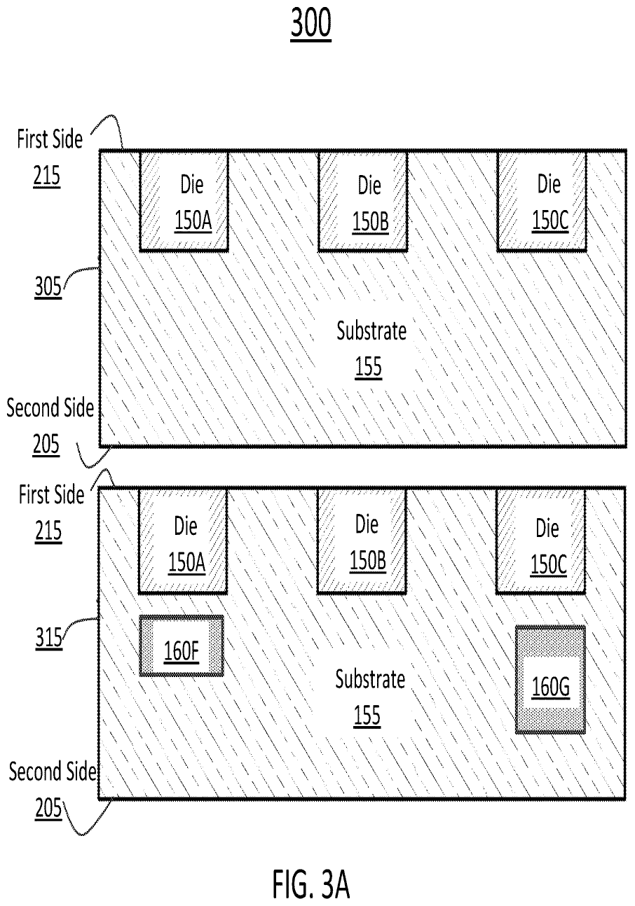

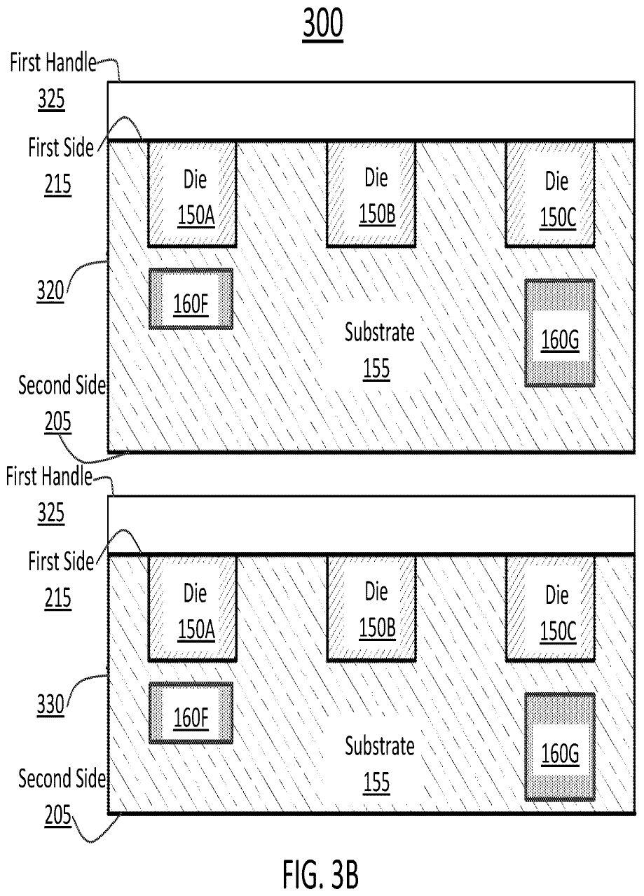

FIGS. 3A-3B illustrate steps of a process 300 to fabricate a semiconductor device with protection features. FIGS. 3A-3B can include steps 305, 315, 320, 330, and 335. Any of the steps depicted in FIGS. 3A-3B can be performed in any order or combination, including steps not shown herein or omitting steps entirely. FIG. 3A can include steps 305 and 315. Steps 305 and 315 can depict the addition of protection features 160 by the laser as described herein. At step 305, the system can receive a semiconductor device. The semiconductor device can have the second side 205 opposing the first side 215. One or more dies 150 can be disposed within the first side of the semiconductor device in the substrate 155. At step 315, the system can create protection features (e.g., a protection feature 160F and a protection feature 160G) in the substrate 155. In some cases, the laser can provide a beam to change a portion of the substrate to an amorphous material.

Referring now to FIG. 3B, optional steps 320 and 330 can be performed to further provide additional protection features responsive to creating the protection features with the laser. At step 320 a first handle 325 can be added to the semiconductor device. The first handle 325 can be added to the first side 215 of the semiconductor device. In some cases, the first handle 325 can be added after the addition of the protection features 160F and 160G. In some cases, the first handle 325 is not added (e.g., step 320 is not performed). The first handle 325 can be attached to the first side 215 of the semiconductor device with any adhesive appropriate for temporarily attaching the first handle 325 to the substrate 155. At step 330, the substrate 155 can be thinned. In some cases, the substrate 155 is thinned responsive to adding the first handle 325 in step 320. The substrate can be thinned from the second side 205. The substrate 155 can be thinned by, for example, backside grinding (BSG), chemical mechanical polishing (CMP), among others. In some cases, the substrate 155 can be thinned to within a range from about 25 μm to 200 μm.

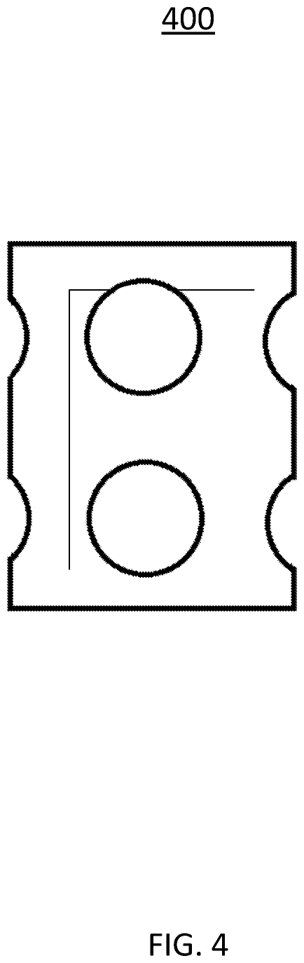

FIG. 4 illustrates a top view 400 of a semiconductor device with protection features. The top view 400 exhibits an example silicon lattice with protection features visible by providing an IR light source, such as from the light source 165.

By the systems and methods depicted herein, the disclosed technical solution creates protection features within semiconductor devices at a variety of depths and lateral positions. Furthermore, the disclosed technical solution creates a variety of protection features using different settings of the laser provided for in the pattern to generate protection features which can vary in size, position, fracture point, among others. In this manner, multiple layers of locally damaged regions (e.g., the protection features) can result in the creation of 3D structures and patterns sequentially built throughout the depth of the substrate.

It should be noted that the laser-based protection features can be used alone or in combination with protection features formed by physical etching.

Having now described these technical solutions, it should be appreciated that elements of different embodiments described herein can be combined to form other embodiments not specifically set forth above. Various elements, which are described in the context of a single embodiment, can also be provided separately or in any suitable sub combination. Other embodiments not specifically described herein also within the scope of the following claims.

It is noted that reference to “any” or “or” are not intended to be exclusive; that is to say, any reference to “any' or “or” can encompass all of the elements to which are being referred. Furthermore, various connection and positional relationships (e.g., over, below, adjacent, etc.) are set forth between elements in the above description and in the drawings. These connections or positional relationships, unless specified otherwise, can be direct or indirect, and the described concepts, systems, devices, structures, and techniques are not intended to be limiting in this respect.

Use of ordinal terms such as “first,” second,” “third,” etc. does not by itself connote any priority, precedence, or order of one elements over another or the temporal order in which acts are performed, but are used merely as labels to distinguish one element from another similarly named element.

Although the disclosed subject matter has been described and illustrated in the foregoing embodiments, it is understood that the present disclosure has been made only by way of example, and that numerous changes in the details of implementation of the disclosed subject matter may be made without departing from the spirit and scope of the disclosed subject matter.

What is claimed is:

1. A system, comprising:
an input for receiving a data representation of a semiconductor device, the semiconductor device having:
a device body with a first side and an opposing second side, the first side being separated from the second side by a thickness of the device body;
a first side separated from an opposing second side by the thickness; and
one or more semiconductor dies;
a laser configured to emit a collimating beam; and
one or more processors, coupled with memory, configured to:
process the data representation of the semiconductor device to construct a pattern of protection features based on locations of the one or more semiconductor dies on the semiconductor device; and
actuate the laser to emit the collimating beam to create protection features in the semiconductor device according to the pattern, while maintaining the thickness of the device body within a threshold range.

2. The system of claim 1, wherein the laser emits the collimating beam to the second side of the semiconductor device to provide the protection features according to the pattern.

3. The system of claim 1, wherein the protection features are configured to reduce a tensile strength of at least one of the semiconductor dies.

4. The system of claim 1, wherein the one or more processors are further configured to:
cause a light source to illuminate the semiconductor device;
cause an imaging device to image the illuminated semiconductor device; and
validate the protection features created in the semiconductor device, including processing the image of the illuminated semiconductor device according to the pattern of protection features.

5. The system of claim 1, wherein the pattern of protection features includes parameter values for configuring the laser.

6. The system of claim 1, wherein the pattern of protection features maps at least one of the semiconductor dies to one or more of the protection features.

7. The system of claim 1, wherein the collimating beam converges at a point disposed within the device body of the semiconductor device, based on the pattern of protection features, to create at least one of the protection features.

8. The system of claim 1, wherein creating at least some of the protection features includes using the collimated light to change a portion of the device body of the semiconductor device from a crystalline state to an amorphous state.

9. The system of claim 1, wherein each protection feature corresponds to a respective die of the dies.

10. The system of claim 1, wherein the threshold range is between 50 μm to 800 μm.

11. The system of claim 1, wherein the threshold range is between 250 μm to 800 μm.

12. The system of claim 1, wherein a first protection feature of the protection features differs from a second protection feature of the protection features in at least a depth within the semiconductor device, size, or structure.

13. The system of claim 1, wherein the one or more semiconductor dies comprises at least one semiconductor feature disposed within the first side of the semiconductor device.

14. The system of claim 1, wherein the pattern defines a set of three-dimensional coordinates for creating the protection features.

15. A method comprising:
receiving a data representation of a semiconductor device, the semiconductor device having:
a device body with a first side and an opposing second side, the first side being separated from the second side by a thickness of the device body;
a first side separated from an opposing second side by the thickness; and
one or more semiconductor dies;
processing the data representation of the semiconductor device to construct a pattern of protection features based on locations of the one or more semiconductor dies on the semiconductor device; and
actuating a laser to emit collimating beam to create protection features in the semiconductor device according to the pattern, while maintaining the thickness of the device body within a threshold range.

16. The method of claim 15, wherein the laser emits the collimating beam to the second side of the semiconductor device to provide the protection features according to the pattern.

17. The method of claim 15, wherein the threshold range is between 50 μm to 800 μm.

18. The method of claim 15, further comprising:
causing a light source to illuminate the semiconductor device;
causing an imaging device to image the illuminated semiconductor device; and
validating the protection features created in the semiconductor device, including processing the image of the illuminated semiconductor device according to the pattern of protection features.

19. The method of claim 15, wherein the collimating beam converges at a point disposed within the semiconductor device, based on the pattern of protection features, to create at least one of the protection features.

20. A semiconductor device comprising:
a device body with a first side and an opposing second side, the first side being separated from the second side by the thickness of the device body;
a first side separated from an opposing second side by the thickness;
one or more semiconductor dies; and
one or more protection features disposed in the device body and configured to reduce a tensile strength of at least one of the semiconductor dies, wherein at least some of the one or more protection features include material in an amorphous state.
